(19) United States
(12) Patent Application Publication
(10) Pub. No.: US 2023/0102607 A1
(43) Pub. Date: Mar. 30, 2023

(54) ELECTRONIC DEVICE

(71) Applicant: SONY SEMICONDUCTOR SOLUTIONS CORPORATION, KANAGAWA (JP)

(72) Inventor: MASASHI NAKATA, KANAGAWA (JP)

(21) Appl. No.: 17/759,499

(22) PCT Filed: Dec. 23, 2020
(86) PCT No.: PCT/JP2020/048174

§ 371 Date: Jul. 26, 2022

(30) Foreign Application Priority Data
Feb. 3, 2020 (JP) 2020-016555

(51) Int. Cl. H04N 25/11; H04N 23/88; H04N 25/772; G02B 5/20

(52) U.S. Cl. CPC H04N 25/11; H04N 23/88; H04N 25/772; G02B 5/201; H01L 27/14645

(57) ABSTRACT

There is provided an electronic device capable of suppressing a decrease in resolution of a captured image while increasing types of information obtained by an imaging unit. An electronic device includes an imaging unit that includes a plurality of pixel groups each including two adjacent pixels, in which at least one first pixel group of the plurality of pixel groups includes a first lens that condenses incident light, a first photoelectric conversion unit that photoelectrically converts a part of the incident light condensed through the first lens, and a second photoelectric conversion unit different from the first photoelectric conversion unit that photoelectrically converts a part of the incident light condensed through the first lens, and at least one second pixel group different from the first pixel group among the plurality of pixel groups includes a second lens that condenses incident light, a third photoelectric conversion unit that photoelectrically converts the incident light condensed through the second lens, and a third lens different from the second lens that condenses the incident light, a fourth photoelectric conversion unit different from the third photoelectric conversion unit that photoelectrically converts the incident light condensed through the third lens.

### TECHNICAL FIELD

The present disclosure relates to an electronic device.

### BACKGROUND ART

Recent electronic devices such as smartphones, mobile phones, and personal computers (PCs) are equipped with cameras so that video phones and moving image capturing can be easily performed. On the other hand, in an imaging unit that captures an image, in addition to normal pixels that output imaging information, special purpose pixels such as polarization pixels and pixels having complementary color filters may be arranged. The polarization pixels are used, for example, for correction of flare, and the pixels having complementary color filters are used for color correction.

However, when a large number of special pixels are arranged, the number of normal pixels decreases, and the resolution of the image captured by the imaging unit may decrease.

### CITATION LIST

### Patent Document

Patent Document 1: Japanese Patent Application Laid-Open No.
Patent Document 2: Japanese Patent Application Laid-Open No. 2012-168339

### SUMMARY OF THE INVENTION

### Problems to be Solved by the Invention

In an aspect of the present disclosure, an electronic device capable of suppressing a decrease in resolution of a captured image while increasing types of information obtained by an imaging unit is provided.

### Solutions to Problems

In order to solve the above problem, the present disclosure provides an electronic device including an imaging unit that includes a plurality of pixel groups each including two adjacent pixels, in which

at least one first pixel group of the plurality of pixel groups includes

a first pixel that photoelectrically converts a part of incident light condensed through a first lens, and

a second pixel different from the first pixel that photoelectrically converts a part of the incident light condensed through the first lens, and

at least one second pixel group different from the first pixel group among the plurality of pixel groups includes

a third pixel that photoelectrically converts incident light condensed through a second lens, and

a fourth pixel that is different from the third pixel and photoelectrically converts incident light condensed through a third lens different from the second lens.

The imaging unit may include a plurality of pixel regions in which the pixel groups are arranged in a two-by-two matrix, and

the plurality of pixel regions may include

a first pixel region that is the pixel region in which four of the first pixel groups are arranged, and

a second pixel region that is the pixel region in which three of the first pixel groups and one of the second pixel groups are arranged.

In the first pixel region, one of a red filter, a green filter, and a blue filter may be arranged corresponding to the first pixel group that receives red light, green light, and blue light.

In the second pixel region, at least two of the red filter, the green filter, and the blue filter may be arranged corresponding to the first pixel group that receives at least two colors among red light, green light, and blue light, and

at least one of the two pixels of the second pixel group may include one of a cyan filter, a magenta filter, and a yellow filter.

At least one of the two pixels of the second pixel group may be a pixel having a blue wavelength region.

A signal processing unit that performs color correction of an output signal output by at least one of the pixels of the first pixel group on the basis of an output signal of at least one of the two pixels of the second pixel group may be further included.

At least one pixel of the second pixel group may have a polarization element.

The third pixel and the fourth pixel may include the polarization element, and the polarization element included in the third pixel and the polarization element included in the fourth pixel may have different polarization orientations.

A correction unit that corrects an output signal of a pixel of the first pixel group by using polarization information based on an output signal of the pixel having the polarization element may be further included.

The incident light may be incident on the first pixel and the second pixel via a display unit, and

the correction unit may remove a polarization component captured when at least one of reflected light or diffracted light generated when passing through the display unit is incident on the first pixel and the second pixel and captured.

The correction unit may perform, on digital pixel data obtained by photoelectric conversion by the first pixel and the second pixel and digitization, subtraction processing of a correction amount based on polarization information data obtained by digitizing a polarization component photoelectrically converted by the pixel having the polarization element, to correct the digital pixel data.

A drive unit that reads charges a plurality of times from each pixel of the plurality of pixel groups in one imaging frame, and

an analog-to-digital conversion unit that performs analog-to-digital conversion in parallel on each of a plurality of pixel signals based on a plurality of times of charge reading

may be further included.

The drive unit may read a common black level corresponding to the third pixel and the fourth pixel.

The plurality of pixels including the two adjacent pixels may have a square shape.

Phase difference detection may be possible on the basis of output signals of two pixels of the first pixel group.

The signal processing unit may perform white balance processing after performing color correction on the output signal.

An interpolation unit that interpolates the output signal of the pixel having the polarization element from an output of a peripheral pixel of the pixel may be further included.

The first to third lenses may be on-chip lenses that condense incident light onto a photoelectric conversion unit of a corresponding pixel.

A display unit may be further included, and the incident light may be incident on the plurality of pixel groups via the display unit.

### BRIEF DESCRIPTION OF DRAWINGS

FIG. 1 is a schematic cross-sectional view of an electronic device according to a first embodiment.

FIG. 2 (a) is a schematic external view of the electronic device of FIG. 1, and (b) is a cross-sectional view taken along line A-A of (a).

FIG. 3 is a schematic plan view for describing a pixel array in an imaging unit.

FIG. 4 is a schematic plan view illustrating a relationship between the pixel array and an on-chip lens array in the imaging unit.

FIG. 5 is a schematic plan view for describing an array of pixels in a first pixel region.

FIG. 6A is a schematic plan view for describing an array of pixels in a second pixel region.

FIG. 6B is a schematic plan view for describing an array of pixels in the second pixel region different from that in FIG. 6A.

FIG. 6C is a schematic plan view for describing an array of pixels in the second pixel region different from those in FIGS. 6A and 6B.

FIG. 7A is a view illustrating a pixel array of the second pixel region regarding an R array.

FIG. 7B is a view illustrating the pixel array of the second pixel region different from that in FIG. 7A regarding the R array.

FIG. 7C is a view illustrating the pixel array of the second pixel region different from those in FIGS. 7A and 7B regarding the R array.

FIG. 8 is a view illustrating a structure of an AA cross section of FIG. 5.

FIG. 9 is a view illustrating a structure of an AA cross section of FIG. 6A.

FIG. 10 is a diagram illustrating a system configuration example of the electronic device.

FIG. 11 is a diagram illustrating an example of a data area stored in a memory unit.

FIG. 12 is a diagram illustrating an example of charge reading drive.

FIG. 13 is a diagram illustrating relative sensitivities of red, green, and blue pixels.

FIG. 14 is a diagram illustrating relative sensitivities of cyan, yellow, and magenta pixels.

FIG. 15 is a schematic plan view for describing a pixel array in an imaging unit according to a second embodiment.

FIG. 16 is a schematic plan view illustrating a relationship between a pixel array and an on-chip lens array in the imaging unit according to the second embodiment.

FIG. 17A is a schematic plan view for describing an array of pixels in a second pixel region.

FIG. 17B is a schematic plan view for describing an array of pixels having different polarization elements from those in FIG. 17A.

FIG. 17C is a schematic plan view for describing an array of pixels having different polarization elements from those in FIGS. 17A and 17B.

FIG. 17D is a schematic plan view for describing an array of the polarization elements regarding the B array.

FIG. 17E is a schematic plan view for describing an array of pixels having different polarization elements from those in FIG. 17D.

FIG. 17F is a schematic plan view for describing an array of pixels having different polarization elements from those in FIGS. 17D and 17E.

FIG. 18 is a view illustrating an AA cross-sectional structure of FIG. 17A.

FIG. 19 is a perspective view illustrating an example of a detailed structure of each polarization element.

FIG. 20 is a view schematically illustrating a state in which flare occurs when an image of a subject is captured by an electronic device.

FIG. 21 is a diagram illustrating signal components included in a captured image of FIG. 20.

FIG. 22 is a diagram conceptually describing correction processing.

FIG. 23 is another diagram conceptually describing correction processing.

FIG. 24 is a block diagram illustrating an internal configuration of the electronic device 1.

FIG. 25 is a flowchart illustrating a processing procedure of an image capturing process performed by the electronic device.

FIG. 26 is a plan view of the electronic device in a case of being applied to a capsule endoscope.

FIG. 27 is a rear view of the electronic device in a case of being applied to a digital single-lens reflex camera.

FIG. 28 is a plan view illustrating an example in which the electronic device is applied to a head mounted display.

FIG. 29 is a view illustrating a current HMD.

### MODE FOR CARRYING OUT THE INVENTION

Hereinafter, an embodiment of an electronic device will be described with reference to the drawings. Although main components of the electronic device will be mainly described below, the electronic device may have components and functions that are not illustrated or described. The following description does not exclude components and functions that are not illustrated or described.

### First Embodiment

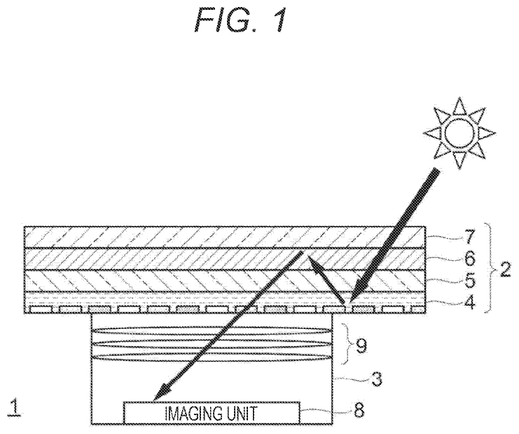

FIG. 1 is a schematic cross-sectional view of an electronic device 1 according to a first embodiment. The electronic device 1 in FIG. 1 is any electronic device having both a display function and an image capturing function, such as a smartphone, a mobile phone, a tablet, or a PC. The electronic device 1 in FIG. 1 includes a camera module (imaging unit) arranged on a side opposite to a display surface of a display unit 2. Thus, in the electronic device 1 of FIG. 1, the camera module 3 is provided on a back side of the display surface of the display unit 2. Therefore, the camera module 3 performs image capturing through the display unit 2.

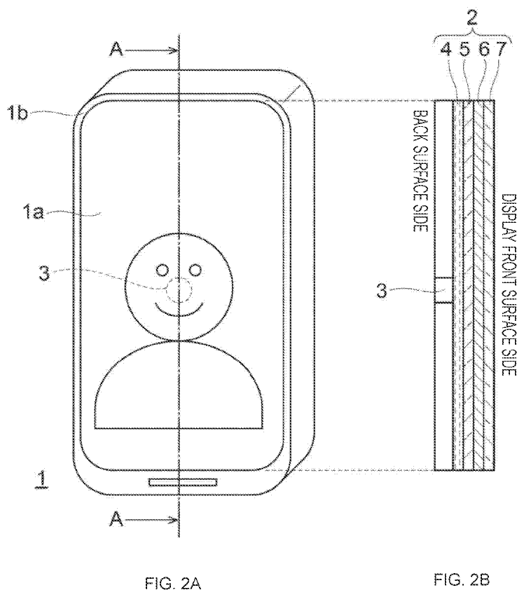

FIG. 2(a) is a schematic external view of the electronic device 1 of FIG. 1, and FIG. 2(b) is a cross-sectional view taken along line A-A of FIG. 2(a). In an example of FIG. 2(a), a display screen 1a spreads close to an outline size of the electronic device 1, and a width of a bezel 1b around the display screen 1a is set to several mm or less. Normally, a front camera is often mounted on the bezel 1b, but in FIG. 2(a), as indicated by a broken line, the camera module 3 functioning as a front camera is arranged on a back surface side of a substantially center portion of the display screen 1a. By providing the front camera on the back surface side of the display screen 1a in this manner, it is not necessary to arrange the front camera in the bezel 1b, and the width of the bezel 1b can be narrowed.

Note that, in FIG. 2(a), although the camera module 3 is arranged on the back surface side of the substantially center portion of the display screen 1a, it is only required to be the back surface side of the display screen 1a in the present embodiment, and for example, the camera module 3 may be arranged on the back surface side near a peripheral edge portion of the display screen 1a. In this manner, the camera module 3 in the present embodiment is arranged at any position on the back surface side overlapping the display screen 1a.

As illustrated in FIG. 1, the display unit 2 is a structure in which a display panel 4, a circularly polarizing plate 5, a touch panel 6, and a cover glass 7 are stacked in this order. The display panel 4 may be, for example, an organic light emitting device (OLED) unit, a liquid crystal display unit, a microLED, or the display unit 2 based on other display principles. The display panel 4 such as the OLED unit includes a plurality of layers. The display panel 4 is often provided with a member having low transmittance such as a color filter layer. As described later, a through hole may be formed in a member having low transmittance in the display panel 4 in accordance with an arrangement place of the camera module 3. If subject light passing through the through hole is made incident on the camera module 3, image quality of an image captured by the camera module 3 can be improved.

The circularly polarizing plate 5 is provided to reduce glare and enhance visibility of the display screen 1a even in a bright environment. A touch sensor is incorporated in the touch panel 6. There are various types of touch sensors such as a capacitive type and a resistive film type, but any type may be used. Furthermore, the touch panel 6 and the display panel 4 may be integrated. The cover glass 7 is provided to protect the display panel 4 and the like.

The camera module 3 includes an imaging unit 8 and an optical system 9. The optical system 9 is arranged on a light incident surface side of the imaging unit 8, that is, on a side close to the display unit 2, and condenses light passing through the display unit 2 on the imaging unit 8. The optical system 9 usually includes a plurality of lenses.

The imaging unit 8 includes a plurality of photoelectric conversion units. The photoelectric conversion unit photoelectrically converts light incident through the display unit 2. The photoelectric conversion unit may be a complementary metal oxide semiconductor (CMOS) sensor or a charge coupled device (CCD) sensor. Furthermore, the photoelectric conversion unit may be a photodiode or an organic photoelectric conversion film.

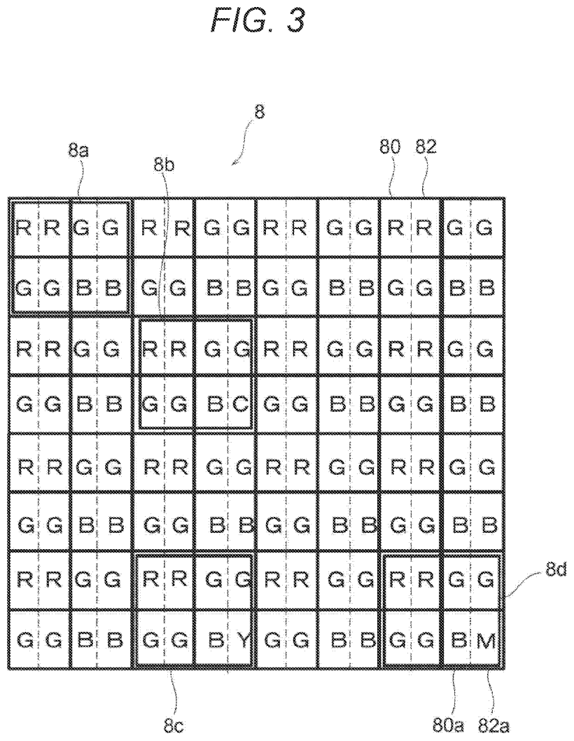

Here, an example of a pixel array and an on-chip lens array in the imaging unit 8 will be described with reference to FIGS. 3 to 6C. The on-chip lens is a lens that is provided on a front surface portion on a light incident side in each pixel and condenses incident light on the photoelectric conversion unit of the corresponding pixel.

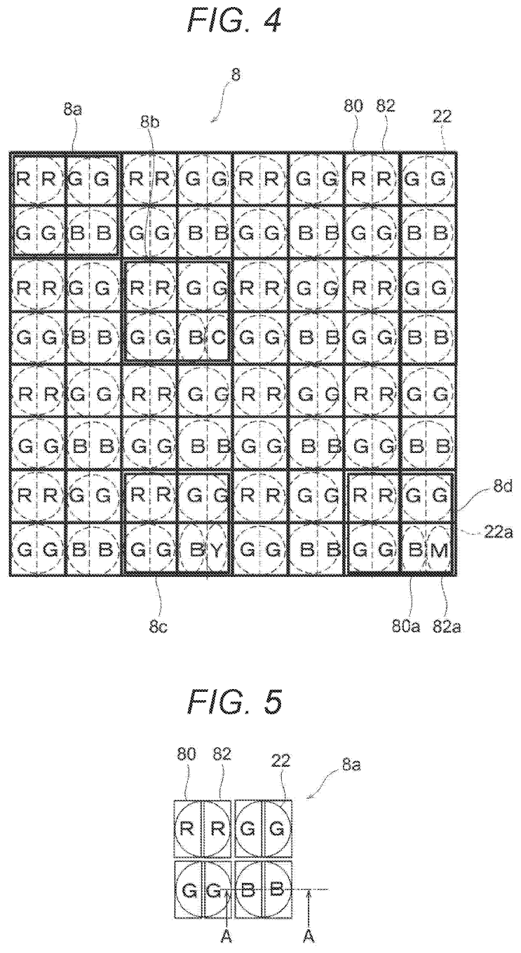

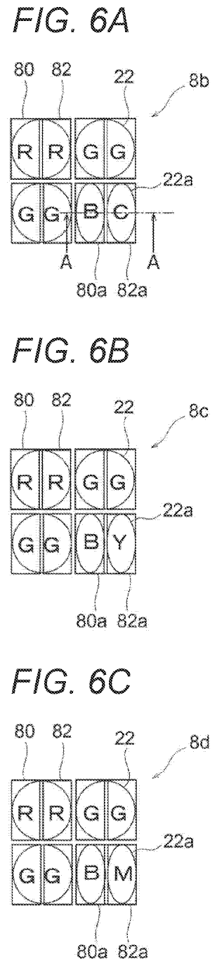

FIG. 3 is a schematic plan view for describing a pixel array in the imaging unit 8. FIG. 4 is a schematic plan view illustrating a relationship between a pixel array and an on-chip lens array in the imaging unit 8. FIG. 5 is a schematic plan view for describing an array of pixels 80 and 82 that form a pair in a first pixel region 8a. FIG. 6A is a schematic plan view for describing an array of pixels 80a and 82a that form a pair in a second pixel region 8b. FIG. 6B is a schematic plan view for describing the array of the pixels 80a and 82a in a second pixel region 8c. FIG. 6C is a schematic plan view for describing the array of the pixels 80a and 82a in a second pixel region 8d.

As illustrated in FIG. 3, the imaging unit 8 includes a plurality of pixel groups each including two adjacent pixels (80, 82) and (80a, 82a) forming a pair. The pixels 80, 82, 80a, and 82a have a rectangular shape, and two adjacent pixels (80, 82) and (80a, 82a) have a square shape.

Reference numeral R denotes a pixel that receives red light, reference numeral G denotes a pixel that receives green light, reference numeral B denotes a pixel that receives blue light, reference numeral C denotes a pixel that receives cyan light, reference numeral Y denotes a pixel that receives yellow light, and reference numeral M denotes a pixel that receives magenta light. The same applies to other drawings.

The imaging unit 8 includes first pixel regions 8a and second pixel regions 8b, 8c, and 8d. In FIG. 3, one group each of the second pixel regions 8b, 8c, and 8d is illustrated. That is, the remaining 13 groups are the first pixel regions 8a.

In a first pixel region 8a, pixels are arranged in a form in which one pixel in a normal Bayer array is replaced with two pixels 80 and 82 arranged in a row. That is, pixels are arranged in a form in which each of R, G, and B in the Bayer array is replaced with two pixels 80 and 82.

On the other hand, in the second pixel regions 8b, 8c, and 8d, pixels are arranged in a form in which each of R and G in the Bayer array is replaced with two pixels 80 and 82, and pixels are arranged in a form in which B in the Bayer array is replaced with two pixels 80a and 82a. For example, the combination of the two pixels 80a and 82a is a combination of B and C in the second pixel region 8b, a combination of B and Y in the second pixel region 8c, and a combination of B and M in the second pixel region 8d.

Further, as illustrated in FIGS. 4 to 6C, one on-chip lens 22 having a circular shape is provided for each of the two pixels 80 and 82. Thus, the pixels 80 and 82 in pixel groups 8a, 8b, 8c, and 8d can detect an image-plane phase difference. Furthermore, by adding outputs of the pixels 80 and 82, the function is equivalent to that of a normal imaging pixel. That is, the imaging information can be obtained by adding the outputs of the pixels 80 and 82.

On the other hand, as illustrated in FIGS. 4 to 6C, an elliptical on-chip lens 22a is provided in each of the two pixels 80a and 82a. As illustrated in FIG. 6A, in the second pixel region 8b, the pixel 82a is different from the B pixel in the first pixel region 8a in that it is a pixel that receives cyan light. Thus, the two pixels 80a and 82a can independently receive the blue light and the cyan light, respectively. Similarly, as illustrated in FIG. 6B, in the second pixel region 8c, the pixel 82a receives the yellow light. Thus, the two pixels 80a and 82a can independently receive the blue light and the yellow light, respectively. Similarly, as illustrated in FIG. 6C, in the second pixel region 8d, the pixel 82a receives the magenta light. Thus, the two pixels 80a and 82a can independently receive the blue light and the magenta light, respectively.

In the first pixel region 8a, pixels in a B array acquire only color information of blue, whereas in the second pixel region 8b, the pixels in the B array can further acquire color information of cyan in addition to the color information of blue. Similarly, the pixels in the B array in the second pixel region 8c can further acquire color information of yellow in addition to the color information of blue. Similarly, the pixels in the B array in the second pixel region 8d can further acquire color information of magenta in addition to the color information of blue.

The color information of cyan, yellow, and magenta acquired by the pixels 80a and 82a in the second pixel regions 8b, 8c, and 8d can be used for color correction. In other words, the pixels 80a and 82a in the second pixel regions 8b, 8c, and 8d are special purpose pixels arranged for color correction. Here, the special purpose pixel according to the present embodiment means a pixel used for correction processing such as color correction and polarization correction. These special purpose pixels can also be used for applications other than normal imaging.

The on-chip lenses 22a of the pixels 80a and 82a in the second pixel regions 8b, 8c, and 8d are elliptical, and the amount of received light is also half the total value of the pixels 80 and 82 that receive the same color. A light reception distribution and an amount of light, that is, sensitivity and the like can be corrected by signal processing.

On the other hand, the pixels 80a and 82a can obtain color information of two different systems, and are effectively used for color correction. In this manner, in the second pixel regions 8b, 8c, and 8d, the types of information to be obtained can be increased without reducing the resolution. Note that details of color correction processing will be described later.

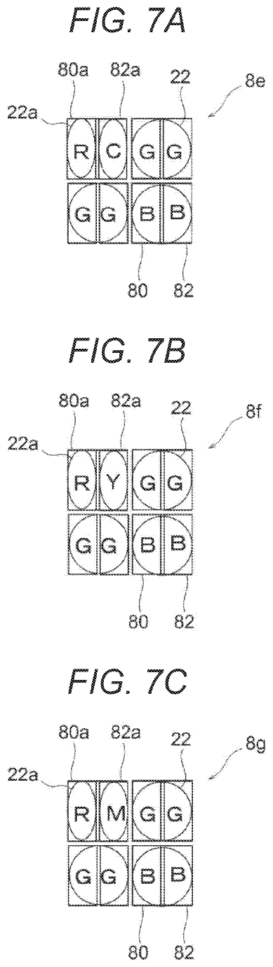

In the present embodiment, the pixels of the B array in the Bayer array are formed by the two pixels 80a and 82a, but the present invention is not limited thereto. For example, as illustrated in FIGS. 7A to 7C, the pixels of an R array in the Bayer array may be formed by two pixels 80a and 82a.

FIG. 7A is a view illustrating a pixel array of the second pixel region 8e. In the second pixel region 8e, the pixel 82a in the R array in the Bayer array is different from the pixel array in the first pixel region 8a in that the pixel receives the cyan light. Thus, the two pixels 80a and 82a can independently receive the red light and the cyan light, respectively.

FIG. 7B is a view illustrating a pixel array of the second pixel region 8f. In the second pixel region 8f, the pixel 82a in the R array in the Bayer array is different from the pixel array in the first pixel region 8a in that the pixel receives the yellow light. Thus, the two pixels 80a and 82a can independently receive the red light and the yellow light, respectively.

FIG. 7C is a view illustrating a pixel array of the second pixel region 8g. In the second pixel region 8g, the pixel 82a in the R array in the Bayer array is different from the pixel array in the first pixel region 8a in that the pixel receives the magenta light. Thus, the two pixels 80a and 82a can independently receive the red light and the magenta light, respectively.

Note that, in the present embodiment, the pixel array is formed by the Bayer array, but the present invention is not limited thereto. For example, an interline array, a checkered array, a stripe array, or other arrays may be used. That is, the ratio of the number of pixels 80a and 82a to the number of pixels 80 and 82, the type of received light color, and the arrangement location are arbitrary.

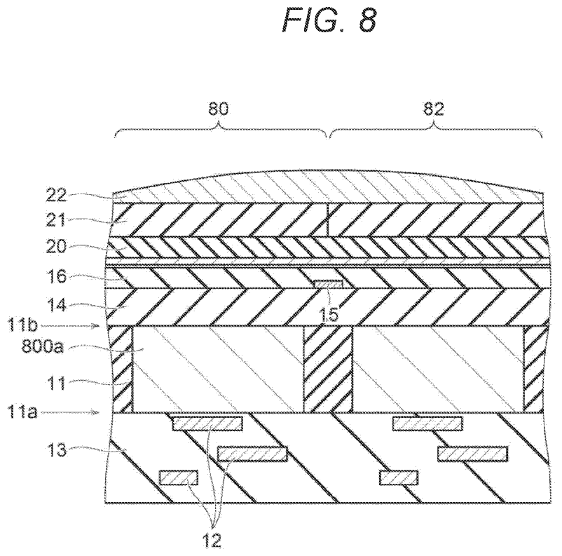

FIG. 8 is a view illustrating a structure of an AA cross section of FIG. 5. As illustrated in FIG. 8, a plurality of photoelectric conversion units 800a is arranged in a substrate 11. A plurality of wiring layers 12 is arranged on a first surface 11a side of the substrate 11. An interlayer insulating film 13 is arranged around the plurality of wiring layers 12. Contacts, which are not illustrated, that connect the wiring layers 12 with each other, the wiring layer 12, and the photoelectric conversion units 800a is provided, but is not illustrated in FIG. 8.

On a second surface 11b side of the substrate 11, a light shielding layer 15 is arranged in the vicinity of a boundary of pixels via a flattening layer 14, and an underlying insulating layer 16 is arranged around the light shielding layer 15. A flattening layer 20 is arranged on the underlying insulating layer 16. A color filter layer 21 is arranged on the flattening layer 20. The color filter layer 21 includes filter layers of three colors of RGB. Note that, in the present embodiment, the color filter layers 21 of the pixels 80 and 82 include filter layers of three colors of RGB, but are not limited thereto. For example, filter layers of cyan, magenta, and yellow, which are complementary colors thereof, may be included. Alternatively, a filter layer that transmits colors other than visible light such as infrared light may be included, a filter layer having multispectral characteristics may be included, or a decoloring filter layer such as white may be included. By transmitting light other than visible light such as infrared light, sensing information such as depth information can be detected. The on-chip lens 22 is arranged on the color filter layer 21.

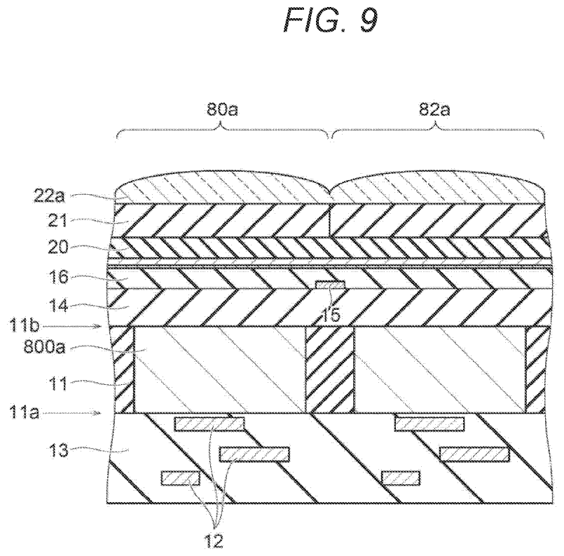

FIG. 9 is a view illustrating a structure of an AA cross section of FIG. 6A. In the cross-sectional structure of FIG. 8, one circular on-chip lens 22 is arranged in the plurality of pixels 80 and 82, but in FIG. 9, an on-chip lens 22a is arranged for each of the plurality of pixels 80a and 82a. The color filter layer 21 of one pixel 80a is, for example, a blue filter. The other pixel 82a is, for example, a cyan filter. In the second pixel regions 8c and d, the other pixel 82a is, for example, a yellow filter or a magenta filter. Furthermore, in the second pixel regions 8e, f, and g, the color filter layer 21 of one pixel 80a is, for example, a red filter. Note that the position of the filter of one pixel 80a may be opposite to the position of the filter of the other pixel 82a. Here, the blue filter is a transmission filter that transmits the blue light, the red filter is a transmission filter that transmits the red light, and a green filter is a transmission filter that transmits the green light. Similarly, each filter of the cyan filter, the magenta filter, and the yellow filter is a transmission filter that transmits the cyan light, the magenta light, and the yellow light.

As can be seen from these, in the pixels 80 and 82 and the pixels 80a and 82a, the shapes of the on-chip lenses 22 and 22a and the combination of the color filter layers 21 are different, but the components of the flattening layers 20 and below have equivalent structures. Therefore, reading of data from the pixels 80 and 82 and reading of data from the pixels 80a and 82a can be performed equally. Thus, as will be described in detail later, the types of information to be obtained can be increased by the output signals of the pixels 80a and 82a, and a decrease in the frame rate can be prevented.

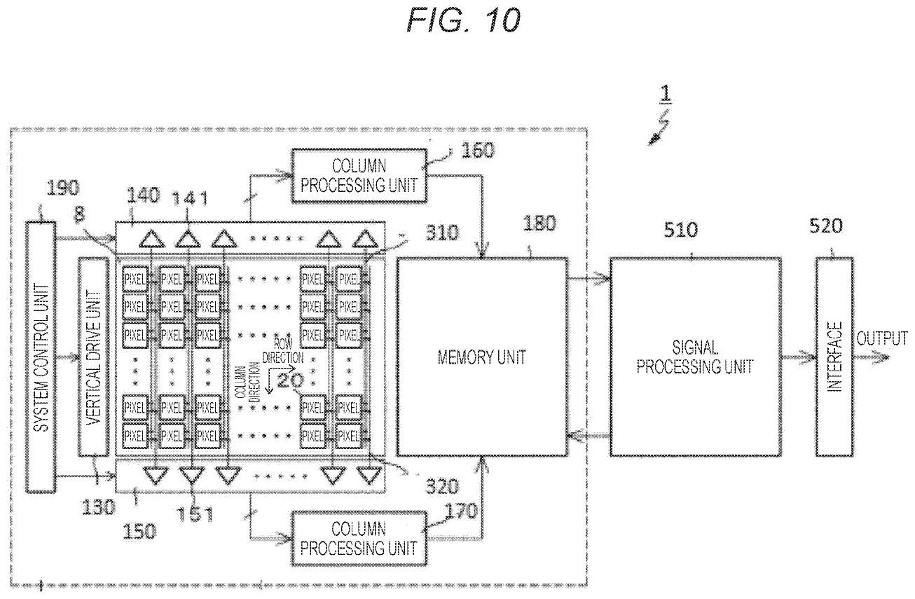

Here, a system configuration example of the electronic device 1 and a data reading method will be described with reference to FIGS. 10, 11, and 12. FIG. 10 is a diagram illustrating a system configuration example of the electronic device 1. The electronic device 1 according to the first embodiment includes an imaging unit 8, a vertical drive unit 130, analog-to-digital conversion (hereinafter described as “AD conversion”) units 140 and 150, column processing units 160 and 170, a memory unit 180, a system control unit 19, a signal processing unit 510, and an interface unit 520.

In the imaging unit 8, pixel drive lines are wired along a row direction for each pixel row and, for example, two vertical signal lines 310 and 32 are wired along a 0 column direction for each pixel column with respect to the pixel array in the matrix form. The pixel drive line transmits a drive signal for driving when a signal is read from the pixels 80, 82, 80a, and 82a. One end of the pixel drive line is connected to an output terminal corresponding to each row of the vertical drive unit 130.

The vertical drive unit 130 includes a shift register, an address decoder, and the like, and drives all the pixels 80, 82, 80a, and 82a of the imaging unit 8 at the same time, in units of rows, or the like. That is, the vertical drive unit 130 forms a drive unit that drives each of the pixels 80, 82, 80a, and 82a of the imaging unit 8 together with a system control unit 190 that controls the vertical drive unit 130. The vertical drive unit 130 generally has a configuration including two scanning systems of a read scanning system and a sweep scanning system. The read scanning system selectively scans each of the pixels 80, 82, 80a, and 82a sequentially in units of rows. Signals read from each of the pixels 80, 82, 80a, and 82a are analog signals. The sweep scanning system performs sweep scanning on a read row, on which read scanning is performed by the read scanning system, prior to the read scanning by a time corresponding to a shutter speed.

By the sweep scanning by the sweep scanning system, unnecessary charges are swept out from each of the photoelectric conversion units of the pixels 80, 82, 80a, and 82a of the read row, and thereby the photoelectric conversion units are reset. Then, by sweeping out (resetting) unnecessary charges by the sweep scanning system, what is called an electronic shutter operation is performed. Here, the electronic shutter operation refers to an operation of discharging photocharges of the photoelectric conversion unit and newly starting exposure (starting accumulation of photocharges).

The signal read by the read operation by the read scanning system corresponds to the amount of light received after the immediately preceding read operation or electronic shutter operation. Then, a period from read timing by the immediately preceding read operation or sweep timing by the electronic shutter operation to the read timing by the current read operation is an exposure period of photocharges in the unit pixel.

Pixel signals output from each of the pixels 80, 82, 80a, and 82a of a pixel row selected by the vertical drive unit 130 are input to the AD conversion units 140 and 150 through the two vertical signal lines 310 and 320. Here, the vertical signal line 310 of one system includes a signal line group (first signal line group) that transmits the pixel signal output from each of the pixels 80, 82, 80a, and 82a of the selected row in a first direction (one side in a pixel column direction/upward direction of the drawing) for each pixel column. The vertical signal line 320 of the other system includes a signal line group (second signal line group) that transmits the pixel signal output from each of the pixels 80, 82, 80a, and 82a of the selected row in a second direction (the other side in the pixel column direction/downward direction in the drawing) opposite to the first direction.

Each of the AD conversion units 140 and 150 includes a set (AD converter group) of AD converters 141 and 151 provided for each pixel column, is provided across the imaging unit 8 in the pixel column direction, and performs AD conversion on the pixel signals transmitted by the vertical signal lines 310 and 320 of the two systems. That is, the AD conversion unit 140 includes a set of AD converters 141 that perform AD conversion on the pixel signals transmitted and input in the first direction by the vertical signal line 31 for each pixel column. The AD conversion unit 150 includes a set of AD converters 151 that perform AD conversion of a pixel signal transmitted in the second direction by the vertical signal line 320 and input for each pixel column.

That is, the AD converter 141 of one system is connected to one end of the vertical signal line 310. Then, the pixel signal output from each of the pixels 80, 82, 80a, and 82a is transmitted in the first direction (upward direction of the drawing) by the vertical signal line 310 and input to the AD converter 141. Furthermore, the AD converter 151 of the other system is connected to one end of the vertical signal line 320. Then, the pixel signal output from each of the pixels 80, 82, 80a, and 82a is transmitted in the second direction (downward of the drawing) by the vertical signal line 320 and input to the AD converter 151.

The pixel data (digital data) after the AD conversion in the AD conversion units 140 and 150 is supplied to the memory unit 180 via the column processing units 160 and 170. The memory unit 180 temporarily stores the pixel data that has passed through the column processing unit 160 and the pixel data that has passed through the column processing unit 170. Furthermore, the memory unit 180 also performs processing of adding the pixel data that has passed through the column processing unit 160 and the pixel data that has passed through the column processing unit 170.

Furthermore, in a case where the black level signal of each of the pixels 80, 82, 80a, and 82a is acquired, the black level to be the reference point may be read in common for each pair of adjacent two pixels (80, 82) and (80a, 82a). Thus, black level reading is made common, and the reading speed, that is, the frame rate can be increased. That is, after the black level serving as the reference point is read in common, it is possible to perform driving of individually reading a normal signal level.

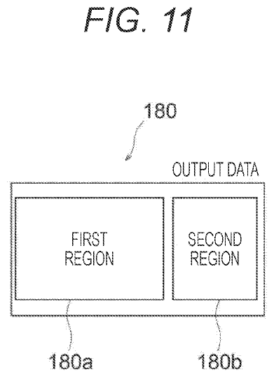

FIG. 11 is a diagram illustrating an example of a data area stored in the memory unit 180. For example, pixel data read from each of the pixels 80, 82, and 80a is associated with pixel coordinates and stored in the first region 180a, and pixel data read from each of the pixels 82a is associated with pixel coordinates and stored in the second region 180b. Thus, the pixel data stored in the first region 180a is stored as R, G, and B image data of the Bayer array, and the pixel data stored in the second region 180b is stored as image data for the correction processing.

The system control unit 190 includes a timing generator that generates various timing signals and the like, and performs drive control of the vertical drive unit 130, the AD conversion units 140 and 150, the column processing units 160 and 170, and the like on the basis of various timings generated by the timing generator.

The pixel data read from the memory unit 180 is subjected to predetermined signal processing in the signal processing unit 510 and then output to the display panel 4 via the interface 520. In the signal processing unit 510, for example, processing of obtaining a sum or an average of pixel data in one imaging frame is performed. Details of the signal processing unit 510 will be described later.

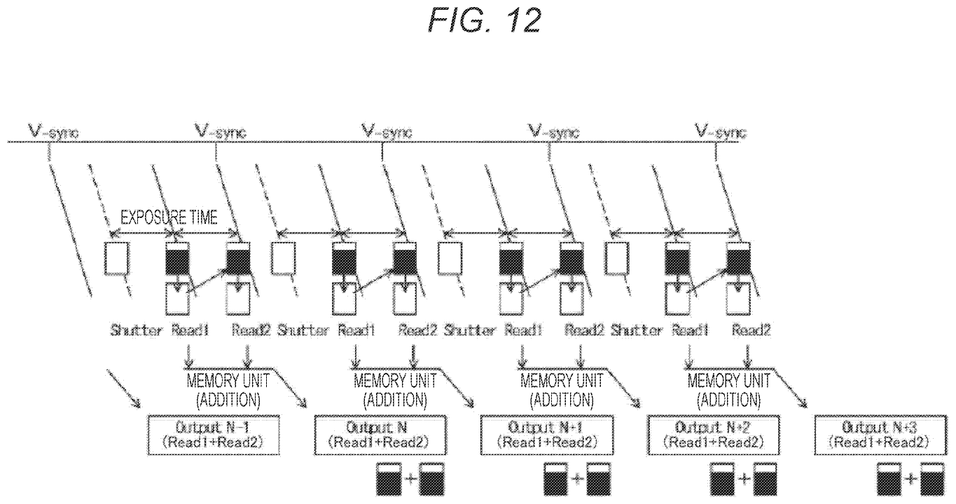

FIG. 12 is a diagram illustrating an example of charge reading drive performed twice. FIG. 12 schematically illustrates a shutter operation, a read operation, a charge accumulation state, and addition processing in a case where charge reading is performed twice from the photoelectric conversion unit 800a (FIGS. 8 and 9).

In the electronic device 1 according to the present embodiment, under control of the system control unit 190, the vertical drive unit 130 performs, for example, charge reading drive twice from the photoelectric conversion unit 800a in one imaging frame. The charge amount corresponding to the number of times of reading can be read from the photoelectric conversion unit 800a by performing reading twice at a faster reading speed than in a case of one-time charge reading, storing in the memory unit 180, and performing addition processing.

The electronic device 1 according to the present embodiment employs a configuration (two-parallel configuration) in which two systems of AD conversion units 140 and 150 are provided in parallel for two pixel signals based on two times of charge reading. Since the two AD conversion units are provided in parallel for the two pixel signals read out in time series from each of the respective pixels 80, 82, 80a, and 82a, the two pixel signals read out in time series can be AD-converted in parallel by the two AD conversion units 140 and 150. In other words, since the AD conversion units 140 and 150 are provided in two systems in parallel, the second charge reading and the AD conversion of the pixel signal based on the second charge reading can be performed in parallel during the AD conversion of the image signal based on the first charge reading. Thus, the image data can be read from the photoelectric conversion unit 800a at a higher speed.

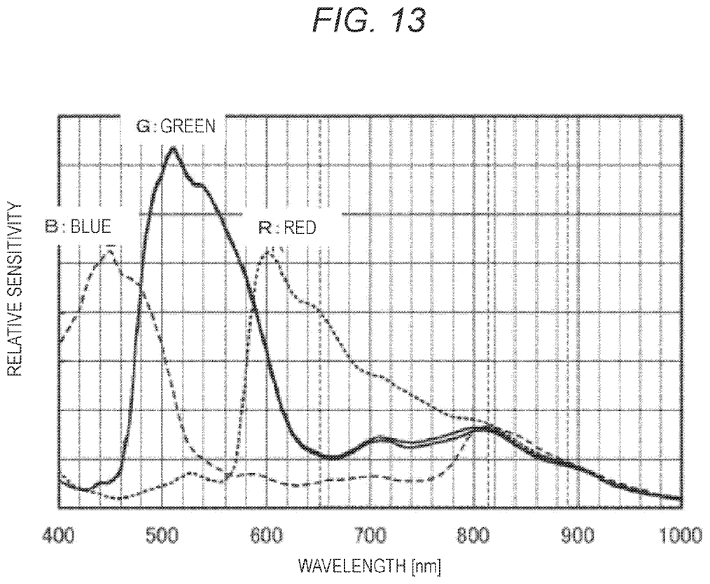

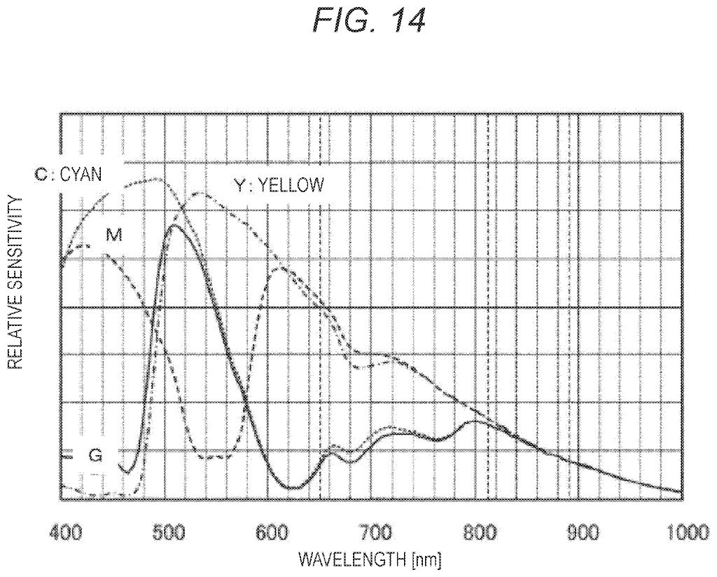

Here, an example of color correction processing of the signal processing unit 510 will be described in detail with reference to FIGS. 13 and 14. FIG. 13 is a diagram illustrating relative sensitivities of R: red, G: green, and B: blue pixels (FIG. 3). The vertical axis represents relative sensitivity, and the horizontal axis represents wavelength. Similarly, FIG. 14 is a diagram illustrating relative sensitivities of C: cyan, Y: yellow, and M: magenta pixels (FIG. 3). The vertical axis represents relative sensitivity, and the horizontal axis represents wavelength. As described above, red (R) pixels have a red filter, blue (B) pixels have a blue filter, green (G) pixels have a green filter, cyan (C) pixels have a cyan filter, yellow (Y) pixels have a yellow filter, and magenta (M) pixels have a magenta filter.

First, correction processing of generating corrected output signals BS3 and BS4 of the B (blue) pixel using an output signal CS1 of the C (cyan) pixel will be described. As described above, an output signal RS1 of the R (red) pixel, an output signal GS1 of the G (green) pixel, and an output signal GB1 of the B (blue) pixel are stored in the first region (180a) of the memory unit 180. On the other hand, the output signal CS1 of the C (cyan) pixel, an output signal YS1 of the Y (yellow) pixel, and an output signal MS1 of the M (magenta) pixel are stored in the second region (180b) of the memory unit 180.

As illustrated in FIGS. 13 and 14, comparing wavelength characteristics of the C (cyan) pixel, the B (blue) pixel, and the G (green) pixel, the output signal CS1 of the C (cyan) pixel can be approximated by adding an output signal BS1 of the B (blue) pixel and the output signal GS1 of the G (green) pixel.

Accordingly, in the second pixel region 8b (FIG. 3), the signal processing unit 510 calculates the output signal BS2 of the B (blue) pixel by, for example, Expression (1).

BS2=k1×CS1−k2×GS1 (1)

Here, k1 and k2 are coefficients for adjusting the signal intensity.

Then, the signal processing unit 510 calculates a corrected output signal BS3 of the B (blue) pixel by, for example, Expression (2).

$$BS 3 = BS 2 + k 3 \times BS 1 \qquad ( 2 )$$

$$= k 1 \times CS 1 - k 2 \times GS 1 + k 3 \times BS 1$$

Here, k3 is a coefficient for adjusting the signal intensity.

Similarly, in the second pixel region 8e (FIG. 7A), the signal processing unit 510 calculates the output signal BS4 of the B (blue) pixel by, for example, Expression (3).

BS4=k1×CS1−k2×GS1+k4×BS1 (3)

Here, k4 is a coefficient for adjusting the signal intensity. In this manner, the signal processing unit 510 can obtain the output signals BS3 and BS4 of the B (blue) pixel corrected using the output signal CS1 of the C (cyan) pixel and the output signal GS1 of the G (green) pixel.

Next, correction processing of generating corrected output signals RS3 and RS4 of the R (red) pixel using the output signal YS1 of the Y (yellow) pixel will be described.

As illustrated in FIGS. 13 and 14, comparing wavelength characteristics of the Y (yellow) pixel, the R (red) pixel, and the G (green) pixel, the output signal YS1 of the Y (yellow) pixel can be approximated by adding the output signal RS1 of the R (red) pixel and the output signal GS1 of the G (green) pixel.

Accordingly, in the second pixel region 8c (FIG. 3), the signal processing unit 510 calculates the output signal RS2 of the R (red) pixel by, for example, Expression (4).

RS2=k5×YS1−k6×GS1 (4)

Here, k5 and k6 are coefficients for adjusting the signal intensity.

Then, the signal processing unit 510 calculates a corrected output signal RS3 of the R (red) pixel by, for example, Expression (5).

$$RS 3 = k 7 \times RS 1 + RS 2 \qquad ( 5 )$$

$$= k 5 \times YS 1 - k 6 \times GS 1 + k 7 \times RS 1$$

Here, k7 is a coefficient for adjusting the signal intensity.

Similarly, in the second pixel region 8f (FIG. 7B), the signal processing unit 510 calculates the output signal RS4 of the R (red) pixel by, for example, Expression (6).

RS4=k5×YS1−k6×GS1+k8×RS1 (6)

Here, k8 is a coefficient for adjusting the signal intensity. In this manner, the signal processing unit 510 can obtain the output signals RS3 and RS4 of the R (red) pixel corrected using the output signal YS1 of the Y (yellow) pixel and the output signal GS1 of the G (green) pixel.

Next, correction processing of generating corrected output signals BS6 and BS7 of the B (blue) pixel using the output signal MS1 of the M (magenta) pixel will be described.

As illustrated in FIGS. 13 and 14, comparing wavelength characteristics of the M (magenta) pixel, the B (blue) pixel, and the R (red) pixel, the output signal MS1 of the M (magenta) pixel can be approximated by adding the output signal BS1 of the B (blue) pixel and the output signal RS1 of the R (red) pixel.

Accordingly, in the second pixel region 8d (FIG. 3), the signal processing unit 510 calculates the output signal BS5 of the B (blue) pixel by, for example, Expression (7).

BS5=k9×MS1−k10×RS1 (7)

Here, k9 and k10 are coefficients for adjusting the signal intensity.

Then, the signal processing unit 510 calculates a corrected output signal BS6 of the B (blue) pixel by, for example, Expression (8).

$$BS 6 = BS 5 + k 11 \times BS 1 \qquad ( 8 )$$

$$= k 9 \times MS 1 - k 10 \times RS 1 + k 11 \times BS 1$$

Here, k11 is a coefficient for adjusting the signal intensity.

Similarly, in the second pixel region 8g (FIG. 7C), the signal processing unit 510 calculates the output signal BS7 of the B (blue) pixel by, for example, Expression (9).

BS7=k9×MS1−k10×RS1+k12×BS1 (9)

Here, k12 is a coefficient for adjusting the signal intensity. In this manner, the signal processing unit 510 can obtain the output signals BS6 and BS7 of the B (blue) pixel corrected using the output signal MS1 of the M (magenta) pixel and the output signal RS1 of the R (red) pixel.

Next, correction processing of generating corrected output signals RS6 and RS7 of the R (red) pixel using the output signal MS1 of the M (magenta) pixel will be described.

In the second pixel region 8d (FIG. 3), the signal processing unit 510 calculates the output signal RS5 of the R (red) pixel by, for example, Expression (10).

RS5=k13×MS1−k14×BS1 (10)

Here, k13 and k14 are coefficients for adjusting the signal intensity.

Then, the signal processing unit 510 calculates a corrected output signal RS6 of the R (red) pixel by, for example, Expression (11).

$$RS 6 = RS 5 + k 15 \times RS 1 \qquad ( 11 )$$

$$= k 13 \times MS 1 - k 14 \times BS 1 + k 16 \times RS 1$$

Here, k16 is a coefficient for adjusting the signal intensity.

Similarly, in the second pixel region 8g (FIG. 7C), the signal processing unit 510 calculates the output signal BS7 of the R (red) pixel by, for example, Expression (12).

RS7=k13×MS1−k14×BS1+k17×RS1 (12)

Here, k17 is a coefficient for adjusting the signal intensity. In this manner, the signal processing unit 510 can obtain the output signals RS6 and RS7 of the R (red) pixel corrected using the output signal MS1 of the M (magenta) pixel and the output signal BS1 of the B (blue) pixel.

Furthermore, the signal processing unit 510 performs various types of processing such as white balance adjustment, gamma correction, and contour emphasizing, and outputs a color image. In this manner, since the white balance adjustment is performed after the color correction is performed on the basis of the output signal of each of the pixels 80a and 82a, a captured image with a more natural color tone can be obtained.

As described above, according to the present embodiment, the imaging unit 8 includes a plurality of pixel groups each including two adjacent pixels, and the first pixel group 80 and 82 including one on-chip lens 22 and the second pixel group 80a and 82a each including the on-chip lens 22a are arranged. Thus, the first pixel group 80 and 82 can detect a phase difference and function as normal imaging pixels, and the second pixel group 80a and 82a can function as special purpose pixels each capable of acquiring independent imaging information. Furthermore, one pixel region area of the pixel group 80a and 82a capable of functioning as special purpose pixels is ½ of the pixel group 80 and 82 capable of functioning as normal imaging pixels, and it is possible to avoid hindrance of the arrangement of the first pixel group 80 and 82 capable of normal imaging.

In the second pixel regions 8b to 8k, which are pixel regions in which the three first pixel groups 80 and 82 and the one second pixel group 80a and 82a are arranged, at least two of a red filter, a green filter, or a blue filter are arranged corresponding to the first pixel groups 80 and 82 that receive at least two colors of red light, green light, and blue light, and any one of a cyan filter, a magenta filter, or a yellow filter is arranged in at least one of the two pixels 80a and 82a of the second pixel group. Thus, the output signal corresponding to any one of the R (red) pixel, the G (green) pixel, and the B (blue) pixel can be subjected to color correction using the output signal corresponding to any one of the C (cyan) pixel, the M (magenta) pixel, and the Y (yellow) pixel. In particular, by performing color correction on the output signal corresponding to any one of the red (R) pixel, the green (G) pixel, and the blue (B) pixel using the output signal corresponding to any one of the cyan (C) pixel and the magenta (M) pixel, it is possible to increase blue information without reducing resolution. In this manner, it is possible to suppress a decrease in resolution of the captured image while increasing the types of information obtained by the imaging unit 8.

### Second Embodiment

An electronic device 1 according to a second embodiment is different from the electronic device 1 according to the first embodiment in that the two pixels 80b and 82b in the second pixel region are formed by pixels having a polarization element. Differences from the electronic device 1 according to the first embodiment will be described below.

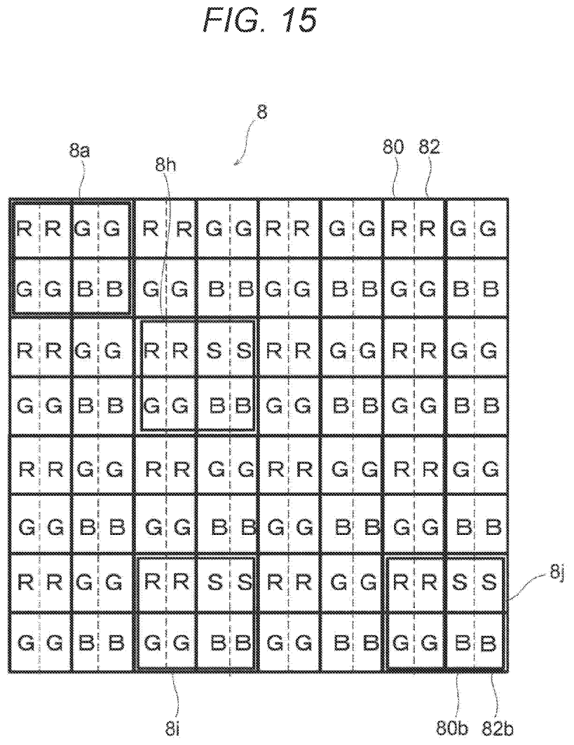

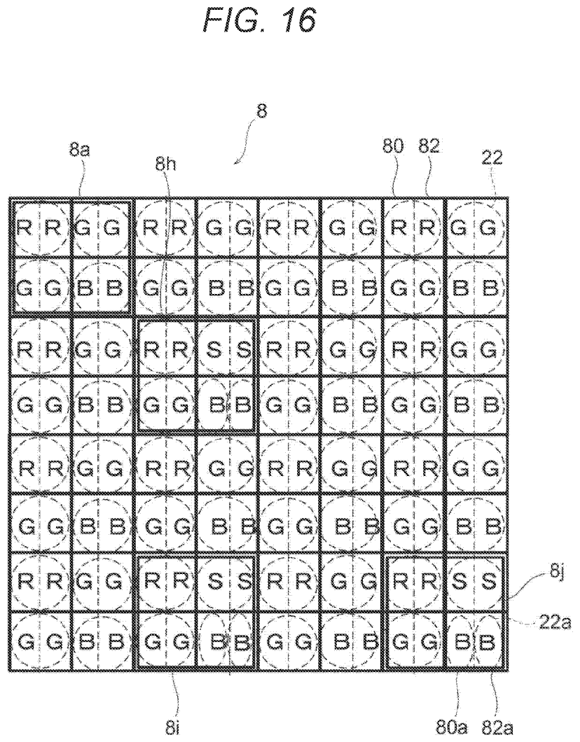

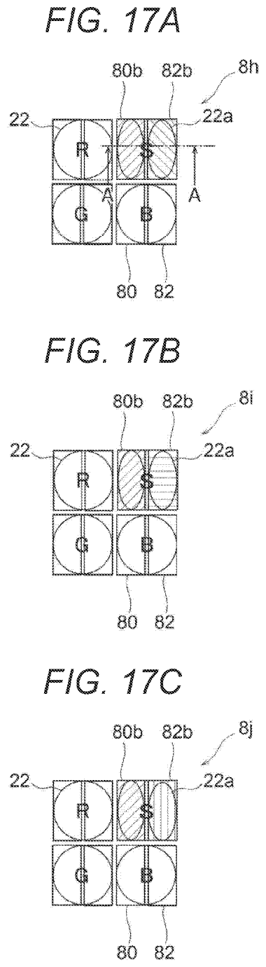

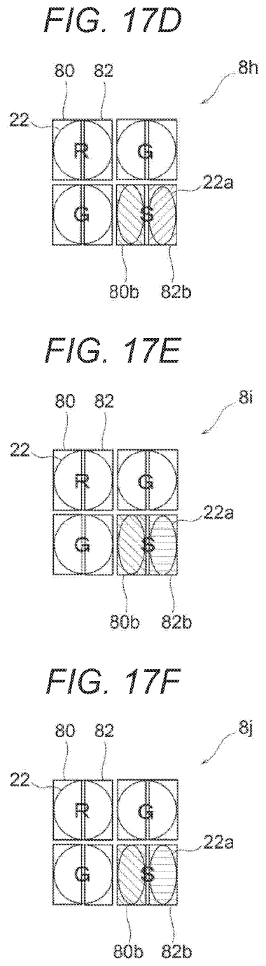

Here, an example of a pixel array and an on-chip lens array in the imaging unit 8 according to the second embodiment will be described with reference to FIGS. 15 to 17C. FIG. 15 is a schematic plan view for describing a pixel array in the imaging unit 8 according to the second embodiment. FIG. 16 is a schematic plan view illustrating a relationship between a pixel array and an on-chip lens array in the imaging unit 8 according to the second embodiment. FIG. 17A is a schematic plan view for describing an array of the pixels 80b and 82b in the second pixel region 8h. FIG. 17B is a schematic plan view for describing an array of the pixels 80b and 82b in the second pixel region 8i. FIG. 17C is a schematic plan view for describing an array of the pixels 80b and 82b in the second pixel region 8j.

As illustrated in FIG. 15, the imaging unit 8 according to the second embodiment includes a first pixel region 8a and second pixel regions 8h, 8i, and 8j. In the second pixel regions 8h, 8i, and 8j, the G pixels 80 and 82 in the Bayer array are respectively replaced with two special purpose pixels 80b and 82b. Note that, in the present embodiment, the G pixels 80 and 82 in the Bayer array are replaced with the special purpose pixels 80b and 82b, but the present invention is not limited thereto. For example, as described later, the B pixels 80 and 82 in the Bayer array may be replaced with the special purpose pixels 80b and 82b.

As illustrated in FIGS. 16 to 17C, similarly to the first embodiment, one on-chip lens 22 having a circular shape is provided for each of the two pixels 80b and 82b. On the other hand, the polarization elements S are arranged in the two pixels 80b and 82b. FIGS. 17A to 17C are plan views schematically illustrating combinations of the polarization elements S arranged in the pixels 80b and 82b. FIG. 17A is a view illustrating a combination of a 45-degree polarization element and a 0-degree polarization element. FIG. 17B is a view illustrating a combination of the 45-degree polarization element and a 135-degree polarization element. FIG. 17C is a view illustrating a combination of the 45-degree polarization element and the 90-degree polarization element. In this manner, in the two pixels 80b and 82b, for example, a combination of polarization elements such as 0 degrees, 45 degrees, 90 degrees, and 135 degrees is possible. Furthermore, as illustrated in FIGS. 17D to 17F, the B pixels 80 and 82 in the Bayer array are replaced with the two pixels 80b and 82b, respectively. In this manner, the pixels are not limited to the G pixels 80 and 82 in the Bayer array, and the pixels may be arranged in a form in which the B and R pixels 80 and 82 in the Bayer array are replaced with two pixels 80b and 82b, respectively. In a case where the G pixels 80 and 82 in the Bayer array are replaced with the special purpose pixels 80b and 82b, it is also possible to obtain the R, G, and B information only by the pixel outputs in the second pixel regions 8h, 8i, and 8j. On the other hand, in a case where the B pixels 80 and 82 in the Bayer array are replaced with the special purpose pixels 80b and 82b, it can be used for phase detection without impairing the output of the G pixel with higher phase detection accuracy. In this manner, each of the pixels 80b and 82b in the second pixel regions 8h, 8i, and 8j can extract the polarization components.

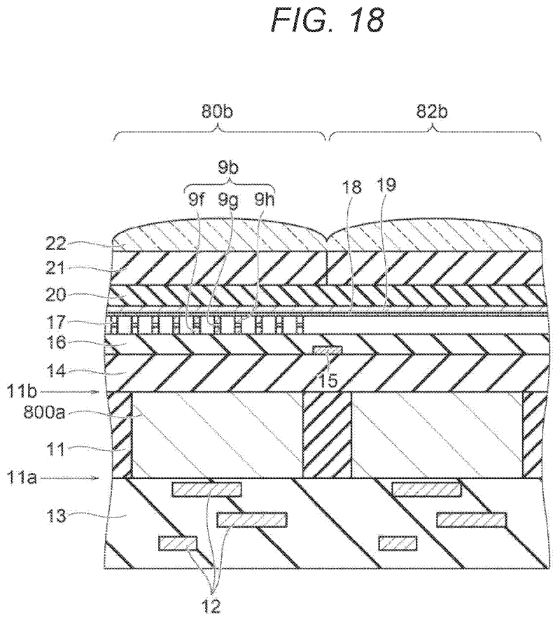

FIG. 18 is a view illustrating an AA cross-sectional structure of FIG. 17A. As illustrated in FIG. 18, a plurality of polarization elements 9b is arranged on the underlying insulating layer 16 in a spaced apart manner. Each polarization element 9b in FIG. 18 is a wire grid polarization element having a line-and-space structure arranged in a part of the insulating layer 17.

FIG. 19 is a perspective view illustrating an example of a detailed structure of each polarization element 9b. As illustrated in FIG. 19, each of the plurality of polarization elements 9b includes a plurality of line portions 9d having a projecting shape extending in one direction and space portions 9e between the line portions 9d. There is a plurality of types of polarization elements 9b in which extending directions of the line portions 9d are different from each other. More specifically, there are three or more types of polarization elements 9b, and for example, the angle between an array direction of the photoelectric conversion units 800a and the extending directions of the line portions 9d may be three types of 0 degrees, 60 degrees, and 120 degrees. Alternatively, the angle between the array direction of the photoelectric conversion units 800a and the extending directions of the line portions 9d may be four types of angles of 0 degrees, 45 degrees, 90 degrees, and 135 degrees, or may be other angles. Alternatively, the plurality of polarization elements 9b may polarize only in a single direction. A material for the plurality of polarization elements 9b may be a metal material such as aluminum or tungsten, or an organic photoelectric conversion film.

In this manner, each polarization element 9b has a structure in which a plurality of line portions 9d extending in one direction is arranged to be spaced apart in a direction intersecting the one direction. There is a plurality of types of polarization elements 9b having different extending directions of the line portion 9d.

The line portion 9d has a stacked structure in which a light reflecting layer 9f, an insulating layer 9g, and a light absorbing layer 9h are stacked. The light reflecting layer 9f includes, for example, a metal material such as aluminum. The insulating layer 9g includes, for example, SiO2 or the like. The light absorbing layer 9h is, for example, a metal material such as tungsten.

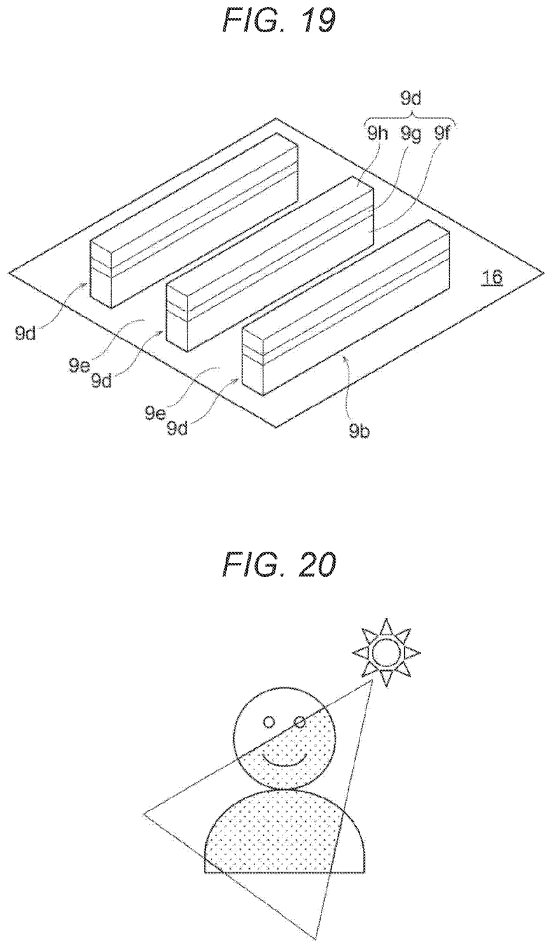

Next, a characteristic operation of the electronic device 1 according to the present embodiment will be described. FIG. 20 is a view schematically illustrating a state in which flare occurs when a subject is imaged by the electronic device 1 of FIG. 1. The flare is caused by that a part of light incident on the display unit 2 of the electronic device 1 is repeatedly reflected by any member in the display unit 2, and then is incident on the imaging unit 8 and captured in the captured image. When the flare occurs in the captured image, a luminance difference or a change in hue occurs as illustrated in FIG. 20, and the image quality is deteriorated.

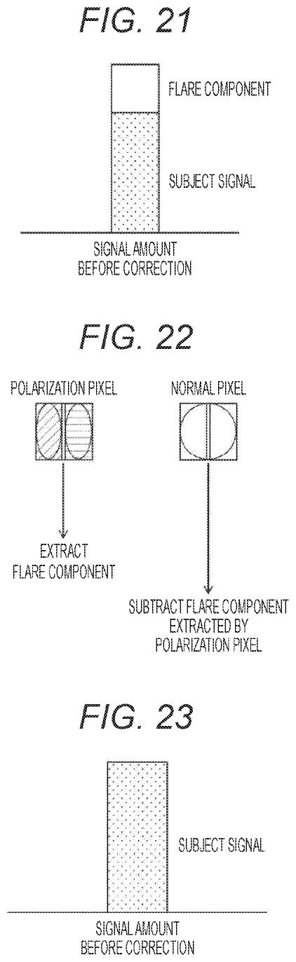

FIG. 21 is a diagram illustrating signal components included in the captured image of FIG. 20. As illustrated in FIG. 21, the captured image includes a subject signal and a flare component.

FIGS. 22 and 23 are diagrams conceptually describing correction processing according to the present embodiment. As illustrated in FIG. 15, the imaging unit 8 according to the present embodiment includes a plurality of polarization pixels 80b and 82b and a plurality of non-polarization pixels 80 and 82. Pixel information photoelectrically converted by the plurality of non-polarization pixels 80 and 82 illustrated in FIG. 15 includes the subject signal and the flare component as illustrated in FIG. 21. On the other hand, polarization information photoelectrically converted by the plurality of polarization pixels 80b and 82b illustrated in FIG. 15 is flare component information. Thus, by subtracting the polarization information photoelectrically converted by the plurality of polarization pixels 80b and 82b from the pixel information photoelectrically converted by the plurality of non-polarization pixels 80 and 82, as illustrated in FIG. 23, the flare component is removed and the subject signal is obtained. When an image based on the subject signal is displayed on the display unit 2, as illustrated in FIG. 23, a subject image from which the flare existing in FIG. 21 has been removed is displayed.

External light incident on the display unit 2 may be diffracted by a wiring pattern or the like in the display unit 2, and diffracted light may be incident on the imaging unit 8. In this manner, at least one of the flare or the diffracted light may be captured in the captured image.

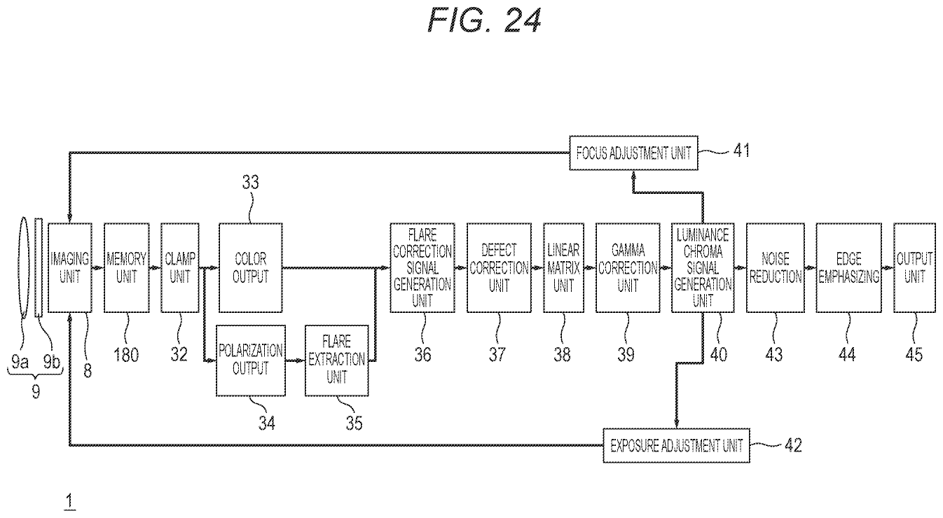

FIG. 24 is a block diagram illustrating an internal configuration of the electronic device 1 according to the present embodiment. The electronic device 1 of FIG. 8 includes an optical system 9, an imaging unit 8, a memory unit 180, a clamp unit 32, a color output unit 33, a polarization output unit 34, a flare extraction unit 35, a flare correction signal generation unit 36, a defect correction unit 37, a linear matrix unit 38, a gamma correction unit 39, a luminance chroma signal generation unit 40, a focus adjustment unit 41, an exposure adjustment unit 42, a noise reduction unit 43, an edge emphasizing unit 44, and an output unit 45. The vertical drive unit 130, the analog-digital conversion units 140 and 150, the column processing units 160 and 170, and the system control unit 19 illustrated in FIG. 10 are omitted in FIG. 24 for simplicity of description.

The optical system 9 includes one or more lenses 9a and an infrared ray (IR) cut-off filter 9b. The IR cut-off filter 9b may be omitted. As described above, the imaging unit 8 includes the plurality of non-polarization pixels 80 and 82 and the plurality of polarization pixels 80b and 82b.

The output values of the plurality of polarization pixels 80b and 82b and the output values of the plurality of non-polarization pixels 80 and 82 are converted by the analog-digital conversion units 140 and 150 (not illustrated), polarization information data obtained by digitizing output values of the plurality of polarization pixels 80b and 82b is stored in the second region 180b (FIG. 11), and digital pixel data obtained by digitizing output values of the plurality of non-polarization pixels 80 and 82 is stored in the first region 180a (FIG. 11).

The clamp unit 32 performs processing of defining a black level, and subtracts black level data from each of the digital pixel data stored in the first region 180a (FIG. 11) of the memory unit 180 and the polarization information data stored in the second region 180b (FIG. 11). Output data of the clamp unit 32 is branched, RGB digital pixel data is output from the color output unit 33, and polarization information data is output from the polarization output unit 34. The flare extraction unit 35 extracts at least one of the flare component or a diffracted light component from the polarization information data. In the present specification, at least one of the flare component or the diffracted light component extracted by the flare extraction unit 35 may be referred to as a correction amount.

The flare correction signal generation unit 36 corrects the digital pixel data by performing subtraction processing of the correction amount extracted by the flare extraction unit 35 on the digital pixel data output from the color output unit 33. Output data of the flare correction signal generation unit 36 is digital pixel data from which at least one of the flare component or the diffracted light component has been removed. In this manner, the flare correction signal generation unit 36 functions as a correction unit that corrects a captured image photoelectrically converted by the plurality of non-polarization pixels 80 and 82 on the basis of the polarization information.

The digital pixel data at pixel positions of the polarization pixels 80b and 82b has a low signal level because of passing through the polarization element 9b. Therefore, the defect correction unit 37 regards the polarization pixels 80b and 82b as defects and performs predetermined defect correction processing. The defect correction processing in this case may be processing of performing interpolation using digital pixel data of surrounding pixel positions.

The linear matrix unit 38 performs matrix operation on color information such as RGB to perform more correct color reproduction. The linear matrix unit 38 is also referred to as a color matrix portion.

The gamma correction unit 39 performs gamma correction so as to enable display with excellent visibility in accordance with display characteristics of the display unit 2. For example, the gamma correction unit 39 converts 10 bits into 8 bits while changing the gradient.

The luminance chroma signal generation unit 40 generates a luminance chroma signal to be displayed on the display unit 2 on the basis of output data of the gamma correction unit 39.

The focus adjustment unit 41 performs autofocus processing on the basis of the luminance chroma signal after the defect correction processing is performed. The exposure adjustment unit 42 performs exposure adjustment on the basis of the luminance chroma signal after the defect correction processing is performed. When the exposure adjustment is performed, the exposure adjustment may be performed by providing an upper limit clip so that the pixel value of each non-polarization pixel 82 is not saturated. Furthermore, in a case where the pixel value of each non-polarization pixel 82 is saturated even if the exposure adjustment is performed, the pixel value of the saturated non-polarization pixel 82 may be estimated on the basis of the pixel value of the polarization pixel 81 around the non-polarization pixel 82.

The noise reduction unit 43 performs processing of reducing noise included in the luminance chroma signal. The edge emphasizing unit 44 performs processing of emphasizing an edge of the subject image on the basis of the luminance chroma signal. The noise reduction processing by the noise reduction unit 43 and the edge emphasizing processing by the edge emphasizing unit 44 may be performed only in a case where a predetermined condition is satisfied. The predetermined condition is, for example, a case where the correction amount of the flare component or the diffracted light component extracted by the flare extraction unit 35 exceeds a predetermined threshold. The more the flare component or the diffracted light component included in the captured image, the more noise or blurring of the edge occurs in the image when the flare component and the diffracted light component are removed. Therefore, by performing the noise reduction processing and the edge emphasizing processing only in a case where the correction amount exceeds the threshold, the frequency of performing the noise reduction processing and the edge emphasizing processing can be reduced.

The signal processing of at least a part of the defect correction unit 37, the linear matrix unit 38, the gamma correction unit 39, the luminance chroma signal generation unit 40, the focus adjustment unit 41, the exposure adjustment unit 42, the noise reduction unit 43, and the edge emphasizing unit 44 in FIG. 24 may be executed by a logic circuit in an imaging sensor including the imaging unit 8, or may be executed by a signal processing circuit in the electronic device 1 on which the imaging sensor is mounted. Alternatively, signal processing of at least a part of FIG. 24 may be executed by a server or the like on a cloud that transmits and receives information to and from the electronic device 1 via a network. As illustrated in the block diagram of FIG. 24, in the electronic device 1 according to the present embodiment, the flare correction signal generation unit 36 performs various types of signal processing on the digital pixel data from which at least one of the flare component or the diffracted light component has been removed. In particular, this is because in some signal processing such as exposure processing, focus adjustment processing, and white balance adjustment processing, even if the signal processing is performed in a state where a flare component or a diffracted light component is included, an excellent signal processing result cannot be obtained.

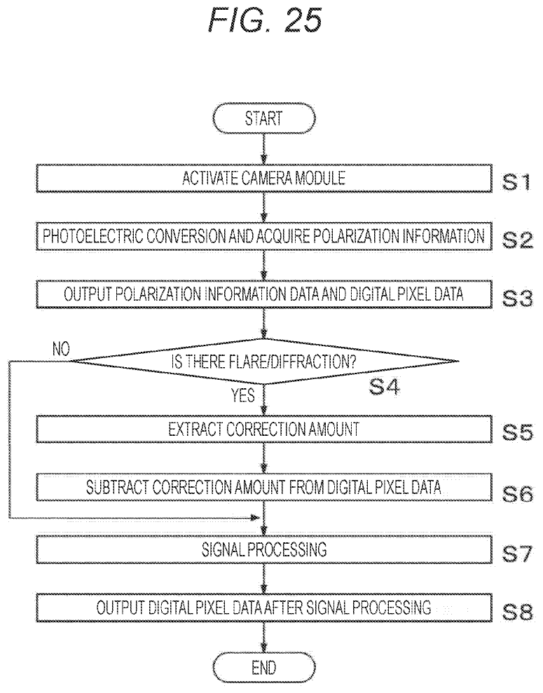

FIG. 25 is a flowchart illustrating a processing procedure of an image capturing process performed by the electronic device 1 according to the present embodiment. First, the camera module 3 is activated (step S1). Thus, a power supply voltage is supplied to the imaging unit 8, and the imaging unit 8 starts imaging the incident light. More specifically, the plurality of non-polarization pixels 80 and 82 photoelectrically converts the incident light, and the plurality of polarization pixels 80b and 82b acquire polarization information of the incident light (step S2). The analog-digital conversion units 140 and 150 (FIG. 10) output polarization information data obtained by digitizing output values of the plurality of polarization pixels 81 and digital pixel data obtained by digitizing output values of the plurality of non-polarization pixels 82, and store the data in the memory unit 180 (step S3).

Next, the flare extraction unit 35 determines whether or not flare or diffraction has occurred on the basis of the polarization information data stored in the memory unit 180 (step S4). Here, for example, if the polarization information data exceeds a predetermined threshold, it is determined that flare or diffraction has occurred. If it is determined that flare or diffraction has occurred, the flare extraction unit 35 extracts the correction amount of the flare component or the diffracted light component on the basis of the polarization information data (step S5). The flare correction signal generation unit 36 subtracts the correction amount from the digital pixel data stored in the memory unit 180 to generate digital pixel data from which the flare component and the diffracted light component have been removed (step S6).

Next, various types of signal processing are performed on the digital pixel data corrected in step S6 or the digital pixel data determined to have no flare or diffraction in step S4 (step S7). More specifically, in step S7, as illustrated in FIG. 8, processing such as defect correction processing, linear matrix processing, gamma correction processing, luminance chroma signal generation processing, exposure processing, focus adjustment processing, white balance adjustment processing, noise reduction processing, and edge emphasizing processing is performed. Note that the type and execution order of the signal processing are arbitrary, and the signal processing of some blocks illustrated in FIG. 24 may be omitted, or signal processing other than the blocks illustrated in FIG. 24 may be performed.

The digital pixel data subjected to the signal processing in step S7 may be output from the output unit 45 and stored in a memory that is not illustrated, or may be displayed on the display unit 2 as a live image (step S8).

As described above, in the second pixel regions 8h to 8k, which are pixel regions in which the three first pixel groups and one second pixel group described above are arranged, the red filter, the green filter, and the blue filter are arranged corresponding to the first pixel groups that receive red light, green light, and blue light, and the pixels 80b and 82b having the polarization elements are arranged in at least one of the two pixels of the second pixel group. The outputs of the pixels 80b and 82b having the polarization elements can be corrected as normal pixels by interpolation using digital pixel data of surrounding pixel positions. This makes it possible to increase the polarization information without reducing the resolution.

In this manner, in the second embodiment, the camera module 3 is arranged on the opposite side of the display surface of the display unit 2, and the polarization information of the light passing through the display unit 2 is acquired by the plurality of polarization pixels 80b and 82b. A part of the light passing through the display unit 2 is repeatedly reflected in the display unit 2 and then incident on the plurality of non-polarization pixels 80 and 82 in the camera module 3. According to the present embodiment, by acquiring the above-described polarization information, it is possible to generate a captured image in a state where the flare component and the diffracted light component included in light incident on the plurality of non-polarization pixels 80 and 82 after repeated reflection in the display unit 2 are simply and reliably removed.

### Third Embodiment

Various candidates can be considered as specific candidates of the electronic device 1 having the configuration described in the first and second embodiments. For example, FIG. 26 is a plan view of the electronic device 1 according to the first and second embodiments in a case of being applied to a capsule endoscope 50. The capsule endoscope 50 of FIG. 26 includes, for example, a camera (ultra-small camera) 52 for capturing an image in a body cavity, a memory 53 for recording image data captured by the camera 52, and a wireless transmitter 55 for transmitting recorded image data to the outside via an antenna 54 after the capsule endoscope 50 is discharged to the outside of the subject in a housing 51 having hemispherical both end surfaces and a cylindrical center portion.

Furthermore, in the housing 51, a central processing unit (CPU) 56 and a coil (magnetic force/current conversion coil) 57 are provided. The CPU 56 controls image capturing by the camera 52 and data accumulation operation in the memory 53, and controls data transmission from the memory 53 to a data reception device (not illustrated) outside the housing 51 by the wireless transmitter 55. The coil 57 supplies power to the camera 52, the memory 53, the wireless transmitter 55, the antenna 54, and a light source 52b as described later.

Moreover, the housing 51 is provided with a magnetic (read) switch 58 for detecting setting of the capsule endoscope 50 in the data reception device when it is set. The CPU 56 supplies power from the coil 57 to the wireless transmitter 55 at a time when the read switch 58 detects a set to the data reception device and data transmission becomes possible.

The camera 52 includes, for example, an imaging element 52a including an objective optical system 9 for capturing an image in a body cavity, and a plurality of light sources 52b for illuminating the body cavity. Specifically, the camera 52 includes, as the light source 52b, for example, a complementary metal oxide semiconductor (CMOS) sensor including a light emitting diode (LED), a charge coupled device (CCD), or the like.

The display unit 2 in the electronic device 1 according to the first and second embodiments is a concept including a light emitter such as the light source 52b in FIG. 26. The capsule endoscope 50 in FIG. 26 includes, for example, two light sources 52b, but these light sources 52b can be configured by a display panel 4 having a plurality of light source units or an LED module having a plurality of LEDs. In this case, by arranging the imaging unit 8 of the camera 52 below the display panel 4 or the LED module, restrictions on the layout arrangement of the camera 52 are reduced, and the capsule endoscope 50 having a smaller size can be achieved.

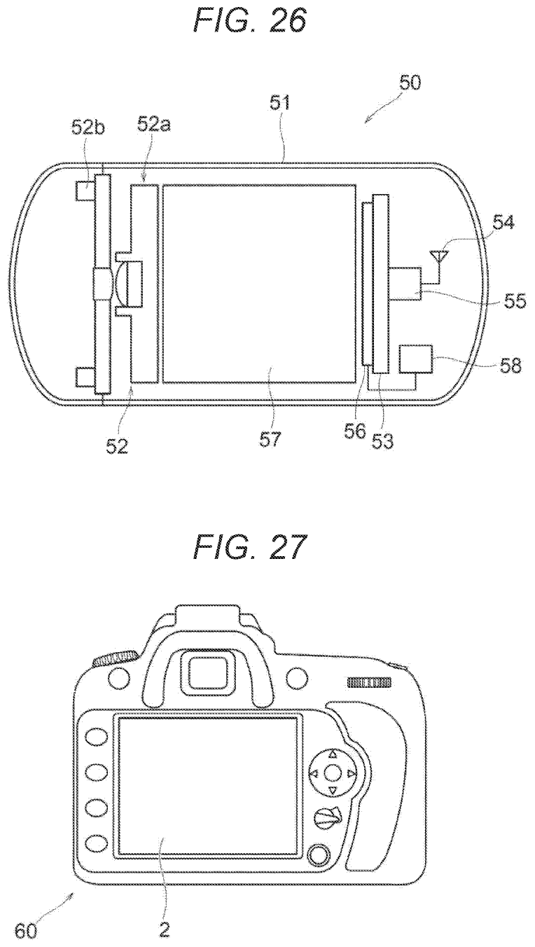

Furthermore, FIG. 27 is a rear view of the electronic device 1 according to the first and second embodiments in a case of being applied to a digital single-lens reflex camera 60. The digital single-lens reflex camera 60 and the compact camera include a display unit 2 that displays a preview screen on a back surface opposite to the lens. The camera module 3 may be arranged on the side opposite to the display surface of the display unit 2 so that a face image of the photographer can be displayed on the display screen 1a of the display unit 2. In the electronic device 1 according to the first to fourth embodiments, since the camera module 3 can be arranged in the region overlapping the display unit 2, it is not necessary to provide the camera module 3 in the frame portion of the display unit 2, and the size of the display unit 2 can be increased as much as possible.

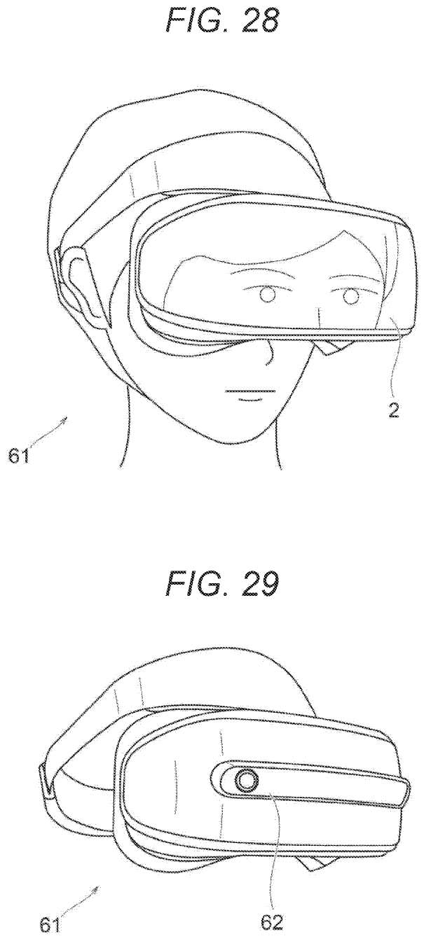

FIG. 28 is a plan view illustrating an example in which the electronic devices 1 according to the first and second embodiments are applied to a head mounted display (HMD) 61. The HMD 61 in FIG. 28 is used for virtual reality (VR), augmented reality (AR), mixed reality (MR), substitutional reality (SR), or the like. As illustrated in FIG. 29, in a current HMD, the camera 62 is mounted on an outer surface, and there is a problem that, while a wearer of the HMD can visually recognize a surrounding image, a person in the surroundings cannot recognize an expression of the eyes or face of the wearer of the HMD.

Accordingly, in FIG. 28, the display surface of the display unit 2 is provided on the outer surface of the HMD 61, and the camera module 3 is provided on the opposite side of the display surface of the display unit 2. Thus, the expression of the face of the wearer captured by the camera module 3 can be displayed on the display surface of the display unit 2, and the person around the wearer can grasp the expression of the face and movement of the eyes of the wearer in real time.

In the case of FIG. 28, since the camera module 3 is provided on the back surface side of the display unit 2, there is no restriction on the installation location of the camera module 3, and the degree of freedom in the design of the HMD 61 can be increased. Furthermore, since the camera can be arranged at an optimum position, it is possible to prevent problems such as misalignment of the eyes of the wearer displayed on the display surface.

In this manner, in the third embodiment, the electronic device 1 according to the first and second embodiments can be used for various applications, and the utility value can be increased.

Note that the present technology can have configurations as follows.

(1) An electronic device including an imaging unit that includes a plurality of pixel groups each including two adjacent pixels, in which

at least one first pixel group of the plurality of pixel groups includes

a first pixel that photoelectrically converts a part of incident light condensed through a first lens, and

a second pixel different from the first pixel that photoelectrically converts a part of the incident light condensed through the first lens, and

at least one second pixel group different from the first pixel group among the plurality of pixel groups includes

a third pixel that photoelectrically converts incident light condensed through a second lens, and

a fourth pixel that is different from the third pixel and photoelectrically converts incident light condensed through a third lens different from the second lens.

(2) The electronic device according to (1), in which

the imaging unit includes a plurality of pixel regions in which the pixel groups are arranged in a two-by-two matrix, and

the plurality of pixel regions includes

a first pixel region that is the pixel region in which four of the first pixel groups are arranged, and

a second pixel region that is the pixel region in which three of the first pixel groups and one of the second pixel groups are arranged.

(3) The electronic device according to (2), in which in the first pixel region, one of a red filter, a green filter, and a blue filter is arranged corresponding to the first pixel group that receives red light, green light, and blue light.

(4) The electronic device according to (3), in which in the second pixel region, at least two of the red filter, the green filter, and the blue filter are arranged corresponding to the first pixel group that receives at least two colors among red light, green light, and blue light, and at least one of the two pixels of the second pixel group includes one of a cyan filter, a magenta filter, and a yellow filter.

(5) The electronic device according to (4), in which at least one of the two pixels of the second pixel group is a pixel having a blue wavelength region.

(6) The electronic device according to (4), further including a signal processing unit that performs color correction of an output signal output by at least one of the pixels of the first pixel group on the basis of an output signal of at least one of the two pixels of the second pixel group.

(7) The electronic device according to (2), in which at least one pixel of the second pixel group has a polarization element.

(8) The electronic device according to (7), in which the third pixel and the fourth pixel include the polarization element, and the polarization element included in the third pixel and the polarization element included in the fourth pixel have different polarization orientations.

(9) The electronic device according to (7), further including a correction unit that corrects an output signal of a pixel of the first pixel group by using polarization information based on an output signal of the pixel having the polarization element.

(10) The electronic device according to (9), in which the incident light is incident on the first pixel and the second pixel via a display unit, and the correction unit removes a polarization component captured when at least one of reflected light or diffracted light generated when passing through the display unit is incident on the first pixel and the second pixel and captured.

(11) The electronic device according to (10), in which the correction unit performs, on digital pixel data obtained by photoelectric conversion by the first pixel and the second pixel and digitization, subtraction processing of a correction amount based on polarization information data obtained by digitizing a polarization component photoelectrically converted by the pixel having the polarization element, to correct the digital pixel data.

(12) The electronic device according to any one of (1) to (11), further including:

a drive unit that reads charges a plurality of times from each pixel of the plurality of pixel groups in one imaging frame; and

an analog-to-digital conversion unit that performs analog-to-digital conversion in parallel on each of a plurality of pixel signals based on a plurality of times of charge reading.

(13) The electronic device according to (12), in which the drive unit reads a common black level corresponding to the third pixel and the fourth pixel.

(14) The electronic device according to any one of (1) to (13), in which the plurality of pixels including the two adjacent pixels has a square shape.

(15) The electronic device according to any one of (1) to (14), in which phase difference detection is possible on the basis of output signals of two pixels of the first pixel group.

(16) The electronic device according to (6), in which the signal processing unit performs white balance processing after performing color correction on the output signal.

(17) The electronic device according to (7), further including an interpolation unit that interpolates the output signal of the pixel having the polarization element from an output of a peripheral pixel of the pixel may be further included.

(18) The electronic device according to any one of (1) to (17), in which the first to third lenses are on-chip lenses that condense incident light onto a photoelectric conversion unit of a corresponding pixel.

(19) The electronic device according to any one of (1) to (18), further including a display unit, in which

the incident light is incident on the plurality of pixel groups via the display unit.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions can be made without departing from the conceptual idea and spirit of the present disclosure derived from the contents defined in the claims and equivalents thereof.

### REFERENCE SIGNS LIST

1 Electronic device
2 Display unit
8 Imaging unit
8a First pixel region
8b to 8k Second pixel region
22 On-chip lens
22a On-chip lens
36 Flare correction signal generation unit
80 Pixel
80a Pixel
82 Pixel
82a Pixel
130 Vertical drive unit
140, 150 Analog-to-digital conversion unit
510 Signal processing unit
800a Photoelectric conversion unit

1. An electronic device comprising an imaging unit that includes a plurality of pixel groups each including two adjacent pixels, wherein
at least one first pixel group of the plurality of pixel groups includes a first pixel that photoelectrically converts a part of incident light condensed through a first lens, and
a second pixel different from the first pixel that photoelectrically converts a part of the incident light condensed through the first lens, and
at least one second pixel group different from the first pixel group among the plurality of pixel groups includes a third pixel that photoelectrically converts incident light condensed through a second lens, and
a fourth pixel that is different from the third pixel and photoelectrically converts incident light condensed through a third lens different from the second lens.

2. The electronic device according to claim 1, wherein
the imaging unit includes a plurality of pixel regions in which the pixel groups are arranged in a two-by-two matrix, and
the plurality of pixel regions includes
a first pixel region that is the pixel region in which four of the first pixel groups are arranged, and
a second pixel region that is the pixel region in which three of the first pixel groups and one of the second pixel groups are arranged.

3. The electronic device according to claim 2, wherein in the first pixel region, one of a red filter, a green filter, and a blue filter is arranged corresponding to the first pixel group that receives red light, green light, and blue light.

4. The electronic device according to claim 3, wherein
in the second pixel region, at least two of the red filter, the green filter, and the blue filter are arranged corresponding to the first pixel group that receives at least two colors among red light, green light, and blue light, and
at least one of the two pixels of the second pixel group includes one of a cyan filter, a magenta filter, and a yellow filter.

5. The electronic device according to claim 4, wherein at least one of the two pixels of the second pixel group is a pixel having a blue wavelength region.

6. The electronic device according to claim 4, further comprising a signal processing unit that performs color correction of an output signal output by at least one of the pixels of the first pixel group on a basis of an output signal of at least one of the two pixels of the second pixel group.

7. The electronic device according to claim 2, wherein at least one pixel of the second pixel group has a polarization element.

8. The electronic device according to claim 7, wherein the third pixel and the fourth pixel include the polarization element, and the polarization element included in the third pixel and the polarization element included in the fourth pixel have different polarization orientations.

9. The electronic device according to claim 7, further comprising a correction unit that corrects an output signal of a pixel of the first pixel group by using polarization information based on an output signal of the pixel having the polarization element.

10. The electronic device according to claim 9, wherein
the incident light is incident on the first pixel and the second pixel via a display unit, and
the correction unit removes a polarization component captured when at least one of reflected light or diffracted light generated when passing through the display unit is incident on the first pixel and the second pixel and captured.

11. The electronic device according to claim 10, wherein the correction unit performs, on digital pixel data obtained by photoelectric conversion by the first pixel and the second pixel and digitization, subtraction processing of a correction amount based on polarization information data obtained by digitizing a polarization component photoelectrically converted by the pixel having the polarization element, to correct the digital pixel data.

12. The electronic device according to claim 1, further comprising:
a drive unit that reads charges a plurality of times from each pixel of the plurality of pixel groups in one imaging frame; and
an analog-to-digital conversion unit that performs analog-to-digital conversion in parallel on each of a plurality of pixel signals based on a plurality of times of charge reading.

13. The electronic device according to claim 12, wherein the drive unit reads a common black level corresponding to the third pixel and the fourth pixel.

14. The electronic device according to claim 1, wherein the plurality of pixels including the two adjacent pixels has a square shape.

15. The electronic device according to claim 1, wherein phase difference detection is possible on a basis of output signals of two pixels of the first pixel group.

16. The electronic device according to claim 6, wherein the signal processing unit performs white balance processing after performing color correction on the output signal.

17. The electronic device according to claim 7, further comprising an interpolation unit that interpolates an output signal of the pixel having the polarization element by using digital pixel data of a pixel position around the pixel.

18. The electronic device according to claim 1, wherein the first to third lenses are on-chip lenses that condense incident light onto a photoelectric conversion unit of a corresponding pixel.

19. The electronic device according to claim 1, further comprising a display unit, wherein
the incident light is incident on the plurality of pixel groups via the display unit.
